(19) United States
(12) Patent Application Publication
(10) Pub. No.: US 2026/0176752 A1
(43) Pub. Date: Jun. 25, 2026

(54) COMPONENT WITH A DUAL LAYER HERMETIC ATOMIC LAYER DEPOSITION COATINGS FOR A SEMICONDUCTOR PROCESSING CHAMBER

(71) Applicant: Lam Research Corporation, Fremont, CA (US)

(72) Inventors: Eric A. PAPE, Santa Cruz, CA (US); David Joseph WETZEL, Santa Clara, CA (US); Lin XU, Fremont, CA (US)

(21) Appl. No.: 19/120,426

(22) PCT Filed: Oct. 9, 2023
(86) PCT No.: PCT/US2023/076373

§ 371 Date: Apr. 11, 2025

Related U.S. Application Data
(60) Provisional application No. 63/420,859, filed on Oct. 31, 2022.

(51) Int. Cl. C23C 16/44; C23C 16/34; C23C 16/455; H01J 37/32

(52) U.S. Cl. CPC C23C 16/4404; C23C 16/34; C23C 16/45525; C23C 16/45527; H01J 37/3244

(57) ABSTRACT

A component for use in a semiconductor processing chamber is provided. A component body of a metal or metal alloy has a process facing surface. An intermediate aluminum oxide coating is on the process facing surface, wherein the intermediate aluminum oxide coating is at least 99% pure by weight and has a porosity of less than 0.1% by volume, and wherein the intermediate aluminum oxide coating has a first thickness. A process exposed layer is on the intermediate aluminum oxide coating, wherein the process exposed layer comprises at least one of yttrium, hafnium, zirconium, lanthanum, magnesium, and a lanthanide, and wherein the process exposed layer is at least 99% pure by weight and has a porosity of less than 0.1% and has a second thickness, wherein the second thickness is less than or equal to the first thickness.

### CROSS-REFERENCE TO RELATED APPLICATION

This application claims the benefit of priority of U.S. Application No. 63/420,859, filed Oct. 31, 2022, which is incorporated herein by reference for all purposes.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

In forming semiconductor devices semiconductor processing chambers are used to process substrates. Some semiconductor processing chambers have component parts that are eroded during semiconductor processing. Coatings may be used to protect the component parts. The deposition of some coatings may be at a high temperature that reduces the mechanical strength of the component parts.

### SUMMARY

To achieve the foregoing and in accordance with the purpose of the present disclosure, a component for use in a semiconductor processing chamber is provided. A component body of a metal or metal alloy has a process facing surface. An intermediate aluminum oxide coating is on the process facing surface, wherein the intermediate aluminum oxide coating is at least 99% pure by weight and has a porosity of less than 0.1% by volume, and wherein the intermediate aluminum oxide coating has a first thickness. A process exposed layer is on the intermediate aluminum oxide coating, wherein the process exposed layer comprises at least one of yttrium, hafnium, zirconium, lanthanum, magnesium, and a lanthanide, and wherein the process exposed layer is at least 99% pure by weight and has a porosity of less than 0.1% and has a second thickness, wherein the second thickness is less than or equal to the first thickness.

In another manifestation, a method for making a component for use in a semiconductor processing chamber is provided. A component body is formed of a metal or metal alloy with a process facing surface. An intermediate layer is deposited on the process facing surface of the component body by atomic layer deposition at a first temperature, wherein the intermediate layer has a first thickness. A process exposed layer is deposited on the intermediate layer by atomic layer deposition at a second temperature that is greater than the first temperature, wherein the process exposed layer has a second thickness that is less than the first thickness.

These and other features of the present disclosure will be described in more detail below in the detailed description and in conjunction with the following figures.

### BRIEF DESCRIPTION OF THE DRAWINGS

The present disclosure is illustrated by way of example, and not by way of limitation, in the figures of the accompanying drawings and in which like reference numerals refer to similar elements and in which:

FIG. 1 is a high level flow chart of an embodiment.

FIG. 2A-B are schematic cross-sectional views of part of an embodiment.

FIG. 3 is a schematic view of a semiconductor processing chamber that may be used in an embodiment.

In the drawings, like reference numerals are sometimes used to designate like structural elements. It should also be appreciated that the depictions in the figures are diagrammatic and not to scale.

### DETAILED DESCRIPTION OF THE PREFERRED EMBODIMENTS

The present disclosure will now be described in detail with reference to a few preferred embodiments thereof as illustrated in the accompanying drawings. In the following description, numerous specific details are set forth in order to provide a thorough understanding of the present disclosure. It will be apparent, however, to one skilled in the art, that the present disclosure may be practiced without some or all of these specific details. In other instances, well-known process steps and/or structures have not been described in detail in order to not unnecessarily obscure the present disclosure.

Spray coating methods are used to deposit protective coatings on process facing surfaces of components of semiconductor processing chambers. These processes are relatively inexpensive and can create coatings tens to thousands of microns thick and are also amenable to coating relatively complex 3-dimensional topologies. However, such processes generate a large number of defects and pores. The holistic impact of this processing technique is that the resulting coating will be porous, relatively rough as processed, have localized domains (chemistry, stresses, crystal structures), uncontrolled stresses, defects, and may have poor mechanical integrity. As a result, such spray coatings do not provide a sufficient hermetic seal.

Porosity can lead to faster corrosive erosion or halogen conversion from plasma chemistry from increased surface area and depth penetration from the surface, and/or increase or trap redeposition of etch byproducts during semiconductor processing or may require a pre-coat step during waferless cleaning to mitigate these detrimental characteristics. A rough surface may trap byproduct adhesion, or the high surface area may be susceptible to large areas of halogen conversion. Localized domain structures and weak interfaces may fracture and release from the coating body or be preferentially attacked via a corrosive or plasma processing environment. All of these above effects may release particles, of nanometer to microns in size, which ultimately end up impacting wafer etch performance.

Atomic layer deposition (ALD) techniques use multi-stage deposition chemistry where each stage reaches an equilibrium. This allows for extremely dense, extremely high quality molecularly smooth films that are uniform regardless of substrate geometry. Most metal oxide and halide deposition processes require high temperatures (>150° C. for depositing aluminum oxide (Al₂O3) or yttrium oxide (Y₂O₃) and >300° C. for most other metal oxides; these temperatures will detemper heat-treated aluminum. ALD processes also tend to be quite slow and expensive due to precursor cycling and purge, and precursor chemistry costs. Some metal oxide coatings, such as Al₂O₃, can be performed relatively inexpensively due to low precursor cost, lower substrate temperature, higher deposition efficiencies because of precursor reactions, and reduced steric hindrance. Higher atomic weight metals often require significantly higher cost precursors, higher substrate temperatures, may have higher porosity due to steric hindrance, and deposit fewer monolayers per chemistry pass. Note that industrial processes may run in a mixed ALD/chemical vapor deposition (CVD) mode for increased throughput, at the expense of film quality and uniformity.

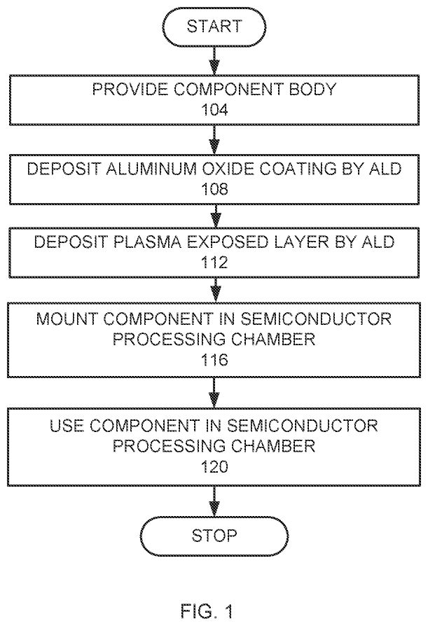

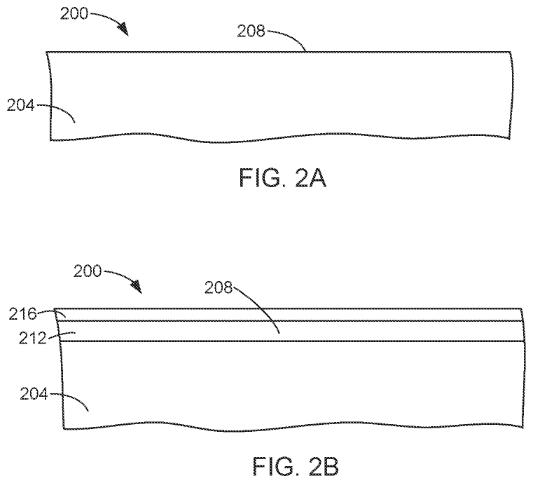

To facilitate understanding, FIG. 1 is a high level flow chart of a process used in an embodiment. A component body is provided (step 104). The component body is a metal or metal alloy component body. For example, the component body is formed from a tempered aluminum alloy, such as T6 grade 6061 aluminum. FIG. 2A is a schematic cross-sectional view of part of a component body 204. The component body 204 has a process facing surface 208. The process facing surface 208 is on a side of the component body 204 that would be closest to a substrate that is processed and/or a vacuum and/or plasma generated during semiconductor processing. In some embodiments, the process facing surface 208 would be exposed to a process plasma and/or vacuum if the process facing surface 208 did not have a protective coating.

An aluminum oxide coating or layer is deposited by atomic layer deposition on the process facing surface 208 (step 108). The ALD of an intermediate aluminum oxide coating is performed at a first temperature to provide an intermediate layer with a first thickness. In some embodiments, the ALD process comprises a plurality of cycles. In each cycle in some embodiments, first, a precursor is deposited. In some embodiments, the precursor is trimethylaluminum (Al₂(CH₃)₆). Next, a first purge is provided. In some embodiments, a purge gas of N₂ is flowed to purge the undeposited precursor. Then, a reactant is applied. In some embodiments, the reactant is water. The reactant oxidizes the aluminum to form a monolayer of alumina (aluminum oxide). Next, a second purge is provided. In some embodiments, a purge gas of N₂ is flowed to purge the reactant that remains as a vapor. This cycle is repeated for a plurality of cycles, forming the ALD alumina coating. In some embodiments, the ALD process is plasmaless. In some embodiments, the coating may be applied to other surfaces of the component body 204 in addition to the process facing surface 208. In some embodiments, the first temperature is in the range of 100° C. to 200° C. In some embodiments, the aluminum oxide coating has a thickness of between 2 nm to 5 μm. In some embodiments, the aluminum oxide coating has a thickness of between 30 nm to 1000 nm. In some embodiments, the ALD of the aluminum oxide coating is deposited on a native oxide layer on one or more surfaces of the component body 204.

A process exposed layer is deposited by atomic layer deposition on the aluminum oxide coating (step 112). The ALD of the process exposed layer is performed at a second temperature. In some embodiments, the process exposed layer comprises yttrium oxide (Y₂O₃). In some embodiments, the ALD of Y₂O₃ coating is performed by providing a plurality of cycles, where each cycle deposits a yttrium layer using a yttrium precursor, such as Tris(cyclopentadienyl)yttrium(II), and then oxidizes the yttrium layer, such as by providing a water vapor. In some embodiments, the process exposed layer comprises at least one of magnesium, yttrium, hafnium, and a lanthanide. In some embodiments, the process exposed layer comprises at least one of Y₂O₃, yttrium trifluoride (YF₃), yttrium oxyfluoride (YOF), magnesium fluoride (MgF₂), hafnium oxide (HfO₂), lanthanide oxide, lanthanum fluoride, lanthanum oxide, and lanthanide fluoride. In some embodiments, the ALD of a Y₂O₃ coating is performed at a temperature of 220° C. In some embodiments, the ALD deposition of the process exposed layer is performed at a second temperature that is greater than the first temperature providing a second thickness that is less than the first thickness. In some embodiments, the second temperature is in the range of 150° C. to 400° C. In some embodiments, the second temperature is in the range of 200° C. to 300° C. In some embodiments, the process exposed layer has a thickness of between 10 nm to 50 nm. In some embodiments, the process exposed layer has a thickness of between 10 nm to 200 nm. In some embodiments, the process exposed layer has a thickness of between 10 nm to 1,000 nm.

In some embodiments, the process exposed layer comprises a pyrochlore. A pyrochlore is a mineral with a general formula of A₂B₂O₇ or A₂B₂O₆, where A and B are 3+ and 4+ metal cations, respectively. In some embodiments, pyrochlore materials are crystalline but accommodate considerable variation in their crystalline structure and stoichiometry. In some embodiments, there may be up to 10% excess A or B site cations. In some embodiments, pyrochlore materials are amorphous. In some embodiments, pyrochlore materials are mixtures of amorphous and crystalline materials. Crystalline materials may be a single crystal material or a multicrystalline material. In some embodiments, the pyrochlore comprises at least one of zirconium and hafnium and at least one of lanthanum (La), samarium (Sm), yttrium (Y), erbium (Er), cerium (Ce), gadolinium (Gd), ytterbium (Yb), and neodymium (Nd). In some embodiments, the pyrochlore comprises at least one of zirconium and hafnium and at least one of La, Ce, and Gd. In some embodiments, the pyrochlore consists essentially of zirconium and La. In some embodiments, the pyrochlore is formed from a material that does not form a volatile halide and is resistant to surface damage from ion bombardment.

In some embodiments, the process exposed layer may be other mixed metal oxides than pyrochlores. For example, in some embodiments, the process exposed layer may comprise yttrium aluminum oxide, such as yttrium aluminum garnet (YAG), yttrium aluminum monoclinic (YAM), and yttrium aluminum perovskite (YAP). In some embodiments, the process exposed layer comprises at least one of magnesium, yttrium, hafnium, zirconium, lanthanum, and a lanthanide. In some embodiments, the process exposed layer comprises at least one of an oxide, fluoride, and oxyfluoride of at least one of yttrium, hafnium, zirconium, lanthanum, and a lanthanide.

FIG. 2B is a schematic cross-sectional view of part of the component body 204 after an aluminum oxide coating 212 is deposited by atomic layer deposition on the process facing surface 208 (step 108) and after a process exposed layer 216 is deposited by atomic layer deposition on the aluminum oxide coating 212 (step 112). The aluminum oxide coating 212 has a first thickness that is greater than a second thickness that is the thickness of the process exposed layer 216.

The component body 204 is mounted in a semiconductor processing chamber (step 116). The component body 204 is used in the semiconductor processing chamber to process a stack (step 120). In some embodiments, the semiconductor processing chamber is used to etch the stack. In some embodiments a plurality of stacks are sequentially processed in the processing chamber.

In some embodiments, providing the aluminum oxide coating by ALD is less expensive than providing the process exposed layer by ALD. By providing a thicker layer of aluminum oxide coating and then a thinner layer of the process exposed layer the component body 204 has increased protection at a lower cost. In addition, in some embodiments, the first temperature used to deposit the aluminum oxide coating is lower than the second temperature used to deposit the process exposed layer. In some embodiments, if the aluminum alloy component body 204 is maintained at the second temperature for a significant period of time, the aluminum alloy component body will lose mechanical strength. In addition, if the component body 204 is T6 grade 6061 aluminum and is maintained at the second temperature for a significant period of time, the component body will lose the T6 grade. If the process exposed layer were deposited to a thickness equal to the first thickness, the component body 204 would be exposed to the second temperature long enough to either cause the component body to lose mechanical strength or the T6 grade or both. By first providing an aluminum oxide coating at a first temperature to a first thickness and then providing a thinner layer of a process exposed layer at a second temperature higher than the first temperature to a second thickness, the component body 204 is exposed to the second temperature for a short enough time so that the component body 204 does not lose mechanical strength and/or T6 grade. Therefore, in some embodiments, after the process exposed layer is deposited, the component body 204 remains a T6 grade 6061 aluminum. In some embodiments, the second temperature does not cause detempering or loss of mechanical strength of the component body 204. In some embodiments, the first temperature is less than 150° C. and the second temperature is greater than 150° C. In some embodiments, the first temperature is less than 200° C. and the second temperature is greater than 200° C.

The deposition of the aluminum oxide coating by atomic layer deposition provides a thin conformal layer. If the aluminum oxide coating was formed by anodization, the ALD of the process exposed layer may cause the anodized aluminum coating to outgas preventing the ALD of the process exposed layer. In addition, in some embodiments, the aluminum oxide coating by ALD is 99.9% pure by weight and has a porosity of less than 0.1% by volume. In some embodiments, the aluminum oxide coating by ALD is 99% pure by weight and has a porosity of less than 0.1% by volume. Anodized aluminum may not have that purity. In some embodiments, the process exposed layer formed by ALD is 99% pure by weight and has a porosity of less than 0.1% by volume. In some embodiments, the process exposed layer formed by ALD is 99.9% pure by weight and has a porosity of less than 0.1% by volume.

In some embodiments, the aluminum oxide coating provides a stress relief layer that reduces the delamination of the process exposed layer. In addition, the aluminum oxide coating can be provided at a lower cost. The thicker ALD aluminum oxide coating provides a precursor, with limited steric hindrance, that can minimize or prevent pinhole defects. In addition, although aluminum oxide coating is not as etch resistant as the process exposed layer, the aluminum oxide coating has a low porosity and is thick enough to provide a hermetic seal and is moderately plasma resistant. In some embodiments, the ALD of aluminum oxide is able to be deposited more quickly and at lower temperatures than some other ALD coatings. Even if the deposition of the process exposed layer is at about the same temperature as the ALD of aluminum oxide, the lower cost and faster ALD of aluminum oxide make ALD of aluminum oxide preferable. In some embodiments, a maximum thickness of 500 nm of yttria can be deposited before risking the temperature failure of aluminum.

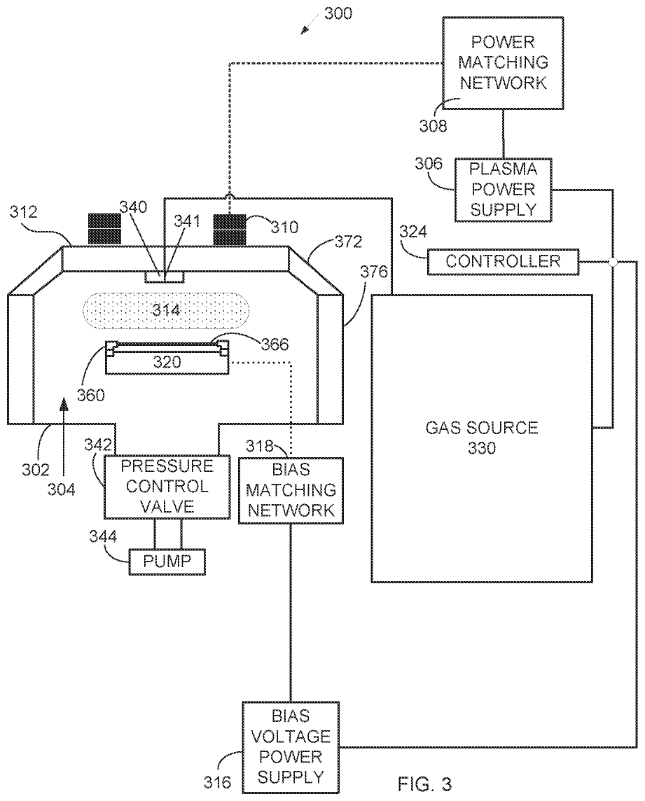

To facilitate understanding, FIG. 3 schematically illustrates an example of a semiconductor processing chamber system 300 that may be used in an embodiment. The semiconductor processing chamber system 300 includes a plasma reactor 302 having a semiconductor processing chamber 304 therein. A plasma power supply 306, tuned by a power matching network 308, supplies power to a transformer coupled plasma (TCP) coil 310 located near a dielectric inductive power window 312 to create a plasma 314 in the semiconductor processing chamber 304 by providing an inductively coupled power. A pinnacle 372 extends from a chamber wall 376 of the semiconductor processing chamber 304 to the dielectric inductive power window 312 forming a pinnacle ring. The pinnacle 372 is angled with respect to the chamber wall 376 and the dielectric inductive power window 312. For example, the interior angle between the pinnacle 372 and the chamber wall 376 and the interior angle between the pinnacle 372 and the dielectric inductive power window 312 may each be greater than 90° and less than 180°. The pinnacle 372 provides an angled ring near the top of the semiconductor processing chamber 304, as shown. The pinnacle 372 is more generally considered a chamber liner. The TCP coil (upper power source) 310 may be configured to produce a uniform diffusion profile within the semiconductor processing chamber 304. For example, the TCP coil 310 may be configured to generate a toroidal power distribution in the plasma 314. The dielectric inductive power window 312 is provided to separate the TCP coil 310 from the semiconductor processing chamber 304 while allowing energy to pass from the TCP coil 310 to the semiconductor processing chamber 304. A wafer bias voltage power supply 316 tuned by a bias matching network 318 provides power to an electrode 320 to set the bias voltage when a stack is placed on the electrode 320. A process wafer 366 is placed over the electrode 320. A controller 324 controls the plasma power supply 306 and the wafer bias voltage power supply 316.

The plasma power supply 306 and the wafer bias voltage power supply 316 may be configured to operate at specific radio frequencies such as, for example, 13.56 megahertz (MHz), 27 MHz, 2 MHz, 60 MHz, 400 kilohertz (kHz), 2.54 gigahertz (GHz), or combinations thereof. Plasma power supply 306 and wafer bias voltage power supply 316 may be appropriately sized to supply a range of powers in order to achieve desired process performance. For example, in one embodiment, the plasma power supply 306 may supply the power in a range of 50 to 5000 Watts, and the wafer bias voltage power supply 316 may supply a bias voltage in a range of 20 to 2000 volts (V). In addition, the TCP coil 310 and/or the electrode 320 may be comprised of two or more sub-coils or sub-electrodes. The sub-coils or sub-electrodes may be powered by a single power supply or powered by multiple power supplies.

As shown in FIG. 3, the semiconductor processing chamber system 300 further includes a gas source/gas supply mechanism 330. The gas source 330 is in fluid connection with semiconductor processing chamber 304 through a gas inlet, such as a gas injector 340. The gas injector 340 has at least one borehole 341 to allow gas to pass through the gas injector 340 into the semiconductor processing chamber 304. The gas injector 340 may be located in any advantageous location in the semiconductor processing chamber 304 and may take any form for injecting gas. Preferably, however, the gas inlet may be configured to produce a “tunable” gas injection profile. The tunable gas injection profile allows independent adjustment of the respective flow of the gases to multiple zones in the semiconductor process chamber 304. More preferably, the gas injector is mounted to the dielectric inductive power window 312. The gas injector may be mounted on, mounted in, or form part of the power window. The process gases and by-products are removed from the semiconductor process chamber 304 via a pressure control valve 342 and a pump 344. The pressure control valve 342 and pump 344 also serve to maintain a particular pressure within the semiconductor processing chamber 304. The pressure control valve 342 can maintain a pressure of less than 1 torr during processing. An edge ring 360 is placed around a top part of the electrode 320. The gas source/gas supply mechanism 330 is controlled by the controller 324. A Kiyo by Lam Research Corp. of Fremont, CA, may be used to practice an embodiment.

Various semiconductor processing chamber systems 300 may use various components with a component body 204, aluminum oxide coating 212, and process exposed layer 216. Such components include chamber liners, such as a chamber pinnacle, and chamber walls. The component 200 may be used in other types of semiconductor processing chambers for etching, deposition, or other semiconductor processes. Examples of other types of semiconductor processing chambers in which the component 200 may be used are capacitively coupled semiconductor processing chambers and bevel semiconductor processing chambers. In some embodiments, the component may be part of a thermal atomic layer etching chamber. The thermal atomic layer etching chamber may use heat instead of plasma to facilitate the thermal etching process. In some embodiments, the process facing surface may be a plasma facing surface or vacuum facing surface, where a vacuum is defined as a region with a pressure of less than 0.1 bar.

While this disclosure has been described in terms of several preferred embodiments, there are alterations, modifications, permutations, and various substitute equivalents, which fall within the scope of this disclosure. It should also be noted that there are many alternative ways of implementing the methods and apparatuses of the present disclosure. It is therefore intended that the following appended claims be interpreted as including all such alterations, modifications, permutations, and various substitute equivalents as fall within the true spirit and scope of the present disclosure. As used herein, the phrase “A, B, or C” should be construed to mean a logical (“A OR B OR C”), using a non-exclusive logical “OR,” and should not be construed to mean ‘only one of A or B or C. Each step within a process may be an optional step and is not required. Different embodiments may have one or more steps removed or may provide steps in a different order. In addition, various embodiments may provide different steps simultaneously instead of sequentially.

What is claimed is:

1. A component for use in a semiconductor processing chamber, comprising:
a component body of a metal or metal alloy with a process facing surface;
an intermediate aluminum oxide coating on the process facing surface, wherein the intermediate aluminum oxide coating is at least 99% pure by weight and has a porosity of less than 0.1% by volume, and wherein the intermediate aluminum oxide coating has a first thickness; and
a process exposed layer on the intermediate aluminum oxide coating, wherein the process exposed layer comprises at least one of yttrium, hafnium, zirconium, lanthanum, magnesium, and a lanthanide, and wherein the process exposed layer is at least 99% pure by weight and has a porosity of less than 0.1% and has a second thickness, wherein the second thickness is less than or equal to the first thickness.

2. The component, as recited in claim 1, wherein the component body is aluminum or an aluminum alloy.

3. The component, as recited in claim 1, wherein the process exposed layer comprises at least one of Y2O3, YF3, YOF, HfO2, lanthanide oxide, lanthanum oxide, lanthanum fluoride, yttrium aluminum oxide, magnesium fluoride, and lanthanide fluoride.

4. The component, as recited in claim 1, wherein the first thickness is in a range of 30 nm to 1000 nm.

5. The component, as recited in claim 1, wherein the second thickness is in a range of 10 nm to 1000 nm.

6. The component, as recited in claim 1, wherein the component body is T6 grade 6061 aluminum.

7. The component, as recited in claim 1, wherein the process exposed layer comprises a mixed metal oxide comprising at least one of zirconium and hafnium and at least one of lanthanum, samarium, yttrium, erbium, cerium, gadolinium, ytterbium, and neodymium.

8. The component, as recited in claim 1, wherein the process exposed layer comprises a mixed metal oxide comprising at least one of zirconium and hafnium and at least one of lanthanum, cerium, and gadolinium.

9. The component, as recited in claim 1, wherein the process exposed layer comprises at least one of MgF2, Y2O3, YF3, HfO2, and yttrium aluminum oxide.

10. A method for making a component for use in a semiconductor processing chamber, comprising:
forming a component body of a metal or metal alloy with a process facing surface;
depositing an intermediate layer on the process facing surface of the component body by atomic layer deposition at a first temperature, wherein the intermediate layer has a first thickness; and
depositing a process exposed layer on the intermediate layer by atomic layer deposition at a second temperature that is greater than the first temperature, wherein the process exposed layer has a second thickness that is less than the first thickness.

11. The method, as recited in claim 10, wherein the process exposed layer comprises at least one of MgF2, Y2O3, YOF, YF3, HfO2, lanthanide oxide, lanthanum oxide, lanthanum fluoride, yttrium aluminum oxide, and lanthanide fluoride.

12. The method, as recited in claim 10, wherein the intermediate layer is an aluminum oxide coating.

13. The method, as recited in claim 10, wherein the first thickness is in a range of 30 nm to 1000 nm.

14. The method, as recited in claim 13, wherein the second thickness is in a range of 10 nm to 1000 nm.

15. The method, as recited in claim 10, wherein the component body is T6 grade 6061 aluminum.

16. The method, as recited in claim 10, wherein the first temperature is less than 200° C. and wherein the second temperature is greater than 200° C.

17. The method, as recited in claim 10, further comprising:
mounting the component in a semiconductor processing chamber, and
using the component in the semiconductor processing chamber.

18. The method, as recited in claim 10, wherein the process exposed layer comprises a mixed metal oxide comprising at least one of zirconium and hafnium and at least one of lanthanum, samarium, yttrium, erbium, cerium, gadolinium, ytterbium, and neodymium.

19. The method, as recited in claim 10, wherein the process exposed layer comprises a mixed metal oxide comprising at least one of zirconium and hafnium and at least one of lanthanum, cerium, and gadolinium.

20. The method, as recited in claim 10, wherein the process exposed layer comprises at least one of Y2O3, YF3, HfO2, MgF2, and yttrium aluminum oxide.
